(19) United States
(12) Patent Application Publication
(10) Pub. No.: US 2017/0253969 A1
(43) Pub. Date: Sep. 7, 2017

(54) VAPORIZATION RAW MATERIAL SUPPLYING DEVICE AND SUBSTRATE PROCESSING APPARATUS USING THE SAME

(71) Applicant: TOKYO ELECTRON LIMITED, Tokyo (JP)

(72) Inventors: Kenji INABA, Oshu-shi (JP); Satoru KOIKE, Oshu-shi (JP)

(21) Appl. No.: 15/446,620

(22) Filed: Mar. 1, 2017

(30) Foreign Application Priority Data
Mar. 3, 2016 (JP) 2016-041317

(51) Int. Cl. C23C 16/455; C23C 16/46; C23C 16/52

(52) U.S. Cl. CPC C23C 16/45544; C23C 16/52; C23C 16/46

(57) ABSTRACT

There is provided a vaporization raw material supplying device, including; a single vaporization raw material producing part configured to vaporize a raw material to produce a vaporization raw material; a plurality of branch pipes connected to the single vaporization raw material producing part and configured to distribute the produced vaporization raw material in multiple channels; and a plurality of mass flow controllers installed respectively in the plurality of branch pipes.

### CROSS-REFERENCE TO RELATED APPLICATION

This application claims the benefit of Japanese Patent Application No. 2016-041317, filed on Mar. 3, 2016, in the Japan Patent Office, the disclosure of Which is incorporated herein in its entirety by reference.

### TECHNICAL FIELD

The present disclosure relates to a vaporization raw material supplying device and a substrate processing apparatus using the same.

### BACKGROUND

Use of a vaporizer and a film forming apparatus are known. In such vaporizer and film forming apparatus, a vaporization raw material gas is obtained by vaporizing a gas-liquid mixed fluid that is formed by vaporizing a portion of a liquid raw material using a vaporizer. A process gas and mist contained in the vaporization raw material gas are separated from each other to obtain the process gas. The process gas is supplied to a film-formation processing part. In this case, the gas-liquid mixed fluid is supplied into a cylindrical part constituting the vaporizer through a fluid supplying part having a plurality of injections holes formed therein, and subsequently, is uniformly spread within the cylindrical part in a state where the gas-liquid mixed fluid is diffused. In this way, the gas-liquid mixed fluid is brought into an easily heat-exchanged state, thereby ensuring high vaporization efficiency. According to this configuration, the process gas and the mist are separated in the vaporizer and the separated mist is discharged. Thus, only the process gas which does not contain the mist may be supplied to the film forming apparatus. Further, in the film forming apparatus using such a vaporizer, a large flow rate of the process gas can be supplied to the film-formation processing part, thereby improving process efficiency.

In recent years, however, in a substrate process such as a film-formation process, a diameter or position of a gas injection hole formed in an injector is sometimes adjusted depending on regions defined inside a processing chamber, from the viewpoint of improvement of in-plane uniformity of a formed film. In other words, for example, in the film forming apparatus, the diameter or number of gas injection holes is adjusted to be increased in a region where a deposition rate tends to be lowered. Meanwhile, the diameter or density of the gas injection hole is adjusted to be decreased in a region where the deposition rate tends to be higher than that in the circumference.

Although in the aforementioned vaporizer and film forming apparatus, there is no disclosure relating to the adjustment of the injector as described above, the adjustment may be performed for the injector.

In the configuration described above, however, even though gas injected from the injector is adjusted at a predetermined flow rate, since flow rates other than the adjusted flow rate are increased or decreased, an internal pressure of the injector may be fluctuated. As a result, a ratio of flow rates corresponding to respective regions becomes different from that at a time when the adjustment has been made. Therefore, even though the adjustment for the injector has been made, if a supply flow rate of a process gas is set differently from that at the time of the adjustment for the injector in different processes, there is a problem that a result as adjusted is not obtained.

### SUMMARY

Some embodiments of the present disclosure provide a vaporization raw material supplying device, which is capable of adjusting a flow rate of a process gas to meet each of a plurality of regions and capable of performing a desired substrate process with high accuracy, and a substrate processing apparatus using the vaporization raw material supplying device.

According to one embodiment of the present disclosure, there is provided a vaporization raw material supplying device, including; a single vaporization raw material producing part configured to vaporize a raw material to produce a vaporization raw material; a plurality of branch pipes connected to the single vaporization raw material producing part and configured to distribute the produced vaporization raw material in multiple channels; and a plurality of mass flow controllers installed respectively in the plurality of branch pipes.

According to another embodiment of the present disclosure, there is provided a substrate processing apparatus, including; the aforementioned vaporization raw material supplying device; a process container configured to accommodate substrates therein; and an injector having a plurality of gas inlet holes and a plurality of gas injection holes, which are formed to correspond to a plurality of regions defined inside the process container, wherein the plurality of branch pipes of the vaporization raw material supplying device is respectively connected to the plurality of gas inlet holes which are formed to correspond to the plurality of regions.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating examples of a vaporization raw material supplying device and a substrate processing apparatus according to a first embodiment of the present disclosure.

FIG. 2 is a view illustrating one more specific example of the vaporization raw material supplying device according to the first embodiment of the present disclosure.

FIG. 3 is a view illustrating an example of a substrate processing apparatus according to a second embodiment of the present disclosure.

FIG. 4 is a view illustrating an example of a substrate processing apparatus according to a third embodiment of the present disclosure.

FIG. 5 is a view showing a cross-section of a process container along a concentric circle of a rotary table from an injector to a reaction gas nozzle in the substrate processing apparatus according to the third embodiment of the present disclosure.

FIG. 6 is a cross-sectional view taken along line I-I′ in FIG. 4, showing a region in which a ceiling surface is formed.

FIG. 7 is a view illustrating an example of a substrate processing apparatus according to a fourth embodiment of the present disclosure.

FIG. 8 is a lateral cross-sectional view of an injector of the substrate processing apparatus according to the fourth embodiment of the present disclosure.

FIG. 9 is a view showing an example of an injector of a substrate processing apparatus according to a fifth embodiment of the present disclosure.

FIG. 10 is a view showing an example of a substrate processing apparatus according to a sixth embodiment of the present disclosure.

FIG. 11 is a view showing a sectional configuration of an example of an injector of the substrate processing apparatus according to the sixth embodiment of the present disclosure.

FIG. 12 is a view showing an example of an injector of a substrate processing apparatus according to a seventh embodiment of the present disclosure.

FIG. 13 is a view showing an example of a substrate processing apparatus according to an eighth embodiment of the present disclosure.

FIG. 14 is a view showing a configuration of an example of an injector of the substrate processing apparatus according to the eighth embodiment of the present disclosure.

FIG. 15 is a view showing an example of an injector of a substrate processing apparatus according to a ninth embodiment of the present disclosure.

FIG. 16 is a view showing an example of an injector of a substrate processing apparatus according to a tenth embodiment of the present disclosure.

### DETAILED DESCRIPTION

Hereinafter, embodiments of the present disclosure will be described with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

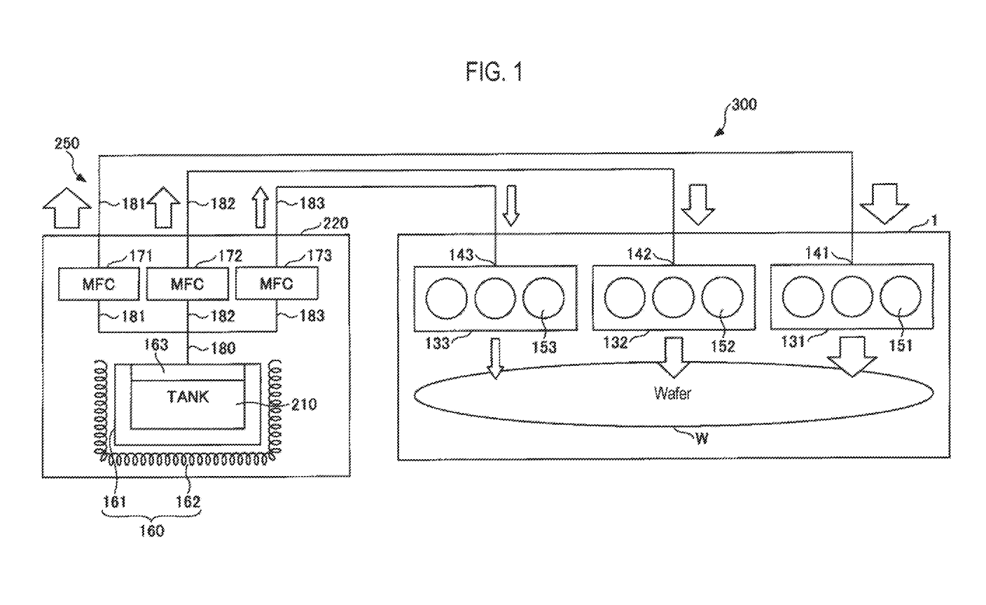

FIG. 1 is a view illustrating examples of a vaporization raw material supplying device and a substrate processing apparatus according to a first embodiment of the present disclosure. In FIG. 1, a vaporization raw material supplying device 250 and a substrate processing apparatus 300 including the same are shown.

The vaporization raw material supplying device 250 is a device for heating a solid (or liquid) raw material to produce a vaporization raw material and supplying the produced vaporization raw material to injectors 131 to 133 of the substrate processing apparatus 300. The vaporization raw material supplying device 250 includes a heating tank 160, mass flow controllers (MFCs) 171 to 173, a main pipe 180, branch pipes 181 to 183 and a casing 220.

The heating tank 160 is a vaporization raw material producing means for producing the vaporization raw material by heating and vaporizing the solid (or liquid) raw material stored therein. The heating tank 160 includes a storage tank 161 and a heater 162.

The storage tank 161 is a means for storing a solid (or liquid) raw material 210 therein. Therefore, the storage tank 161 is configured as a container capable of storing the solid (or liquid) raw material 210 therein. When the vaporization raw material is produced by heating and vaporizing the raw material 210, the vaporization raw material thus produced is required to be stored in a vaporization space 163 of the storage tank 161. Thus, the storage tank 161 is configured as a hermetically-sealable container. Further, since the storage tank 161 is heated by the heater 162, the storage tank is made of a material having sufficient heat resistance.

Furthermore, various solid (or liquid) materials that can be employed as raw materials for a substrate process such as a film formation process while maintaining a vaporized state, may be used as the raw material 210. For example, in case of a process of forming a silicon-containing film tris(dimethylamino)silane (3DMAS) or the like may be used as the raw material 210. The raw material which stays in a solid state may include a powdery raw material.

The heater 162 is a heating means for externally heating the storage tank 161 so as to vaporize the raw material 210 stored in the storage tank 161. The heater 162 may have various structures as long as it can heat and vaporize the raw material 210 to produce the vaporization raw material. For example, the heater 162 may be configured by a heating wire or a plate-shaped heating plate.

The mass flow controllers 171 to 173 are flow rate adjusting means for setting and adjusting a flow rate of the vaporization raw material to be supplied. The mass flow controllers 171 to 173 are installed in multiple channels. In FIG. 1, the mass flow controllers 171 to 173 are installed in three channels. By installing the plurality of mass flow controllers 171 to 173 in this way, it is possible to control the flow rate of the vaporization raw material, which is supplied as process gases into the process container 1 of the substrate processing apparatus 300, through the multiple channels. This makes it possible to individually control respective flow rates to be supplied to a plurality of regions, thus setting different flow rates with respect to the plurality of regions.

The mass flow controllers 171 to 173 are connected to the main pipe 180 through the respective branch pipes 181 to 183. The main pipe 180 is connected to an upper face of the heating tank 160. The vaporization space 163 defined in an upper portion of the heating tank 160 is filled with the vaporization raw material that has been vaporized inside the healing tank 160. Since the main pipe 180 is connected to the upper face of the heating tank 160, the vaporization raw material flows out from the main pipe 180. The branch pipes 181 to 183 branched into the multiple channels are connected to the main pipe 180 so that the vaporization raw material is distributed to and flows through the respective branch pipes 181 to 183. Flow rates of the vaporization raw material flowing through the multiple channels are controlled by the respective mass flow controllers 171 to 173. Subsequently, the vaporization raw material is supplied into the process container 1 via the branch pipes 181 to 183 formed to extend outward of the vaporization raw material supplying device 250.

Here, various types of mass flow controllers may be employed as the mass flow controllers 171 to 173 as long as they can adjust a flow rate of a gas. In some embodiments, the mass flow controllers 171 to 173 may not be identical to each other in configuration. As an example, the mass flow controllers 171 to 173 may have different configurations depending on uses of the respective multiple channels. In particular, if flow rates set in the multiple channels are largely different from one another, mass flow controllers having different capabilities, i.e., different maximum set flow rates, which correspond to the set flow rates, may be used as the mass flow controllers 171 to 173. In general, the flow rates can be adjusted with high accuracy up to about 10% or more of the maximum set flow rate in each of the mass flow controllers 171 to 173. However, it is difficult to adjust a small flow rate of less than 10% of the maximum set flow rate with high accuracy. Therefore, a mass flow controller whose maximum set flow rate is small may be used for a channel in which a set flow rate is small, while a mass flow controller whose maximum set flow rate is large may be used for a channel in which a set flow rate is large. By selecting a respective mass flow controller such that a flow rate to be adjusted is not less than 10% (i.e., is at least 10%) of the maximum set flow rate according to a setting flow rate of a respective channel, it is possible to control the flow rate with very high accuracy.

Although in the above embodiment, the plurality of branch pipes 181 to 183 has been configured to be branched from the main pipe 180, each of the plurality of branch pipes 181 to 183 may be connected directly to the heating tank 160.

In addition, the heating tank 160, the mass flow controllers 171 to 173, the main pipe 180 and the branch pipes 181 to 183 may be housed in the casing 220 so that they are integrally configured. The housing of the respective components in the casing 220 facilities the installation and movement of the vaporization raw material supplying device 250.

Here, the plurality of mass flow controllers 171 to 173 is installed, whereas only one heating tank 160 may be installed. In a case where the vaporization raw material is distributed into the multiple channels and separately supplied to the multiple channels, the heating tank 160 and the mass flow controllers 171 to 173 may be individually installed in each of the multiple channels. However, such a configuration increases a space required for the heating tank 160, which makes a vaporization raw material controlling device bulky. Moreover, the configuration requires a plurality of heating tanks, which increase cost.

In the vaporization raw material supplying device 250 according to the present embodiment, only one heating tank 160 and the plurality of mass flow controllers 171 to 173 has been described to be installed. With this configuration, it is possible to achieve space savings and accurately control flow rates in a plurality of regions.

The substrate processing apparatus 300 is to perform a process such as a film formation process on a substrate, and includes at least the process container 1 and the injectors 131 to 133. The process container 1 is a container configured to receive a target substrate to be processed. In FIG. 1, a semiconductor wafer W is used as the substrate. Hereinafter, an example using the wafer W as the target substrate will be described.

The injectors 131 to 133 are a process gas supplying means configured to supply a process gas to the wafer W. The injectors 131 to 133 are configured in the form of a nozzle. The nozzle may be formed in a cylindrical shape or a prismatic shape such as a rectangular column. Therefore, the injectors 131 to 133 may be referred to as gas nozzles 131 to 133. In addition, in this embodiment, the vaporization raw material produced by vaporizing the solid (or liquid) raw material 210 is used as the process gas.

In order to supply the vaporization raw material to a plurality of regions defined inside the process container 1 or to a plurality of regions on the wafer W, the injector 131 to 133 are respectively installed in the plurality of regions defined inside the process container 1. Therefore, the injectors 131 to 133 are installed at multiple locations. The plurality of injectors 131 to 133 has respectively gas inlet holes 141 to 143 and at least one gas injection holes 151 to 153, which are formed therein. Typically, each of the gas injection holes 151 to 153 is formed at multiple locations in each of the regions. In FIG. 1, an example in which three gas injection holes are formed in each of the injectors 131 to 133 is schematically shown. Actually, in many cases, several tens of gas injection holes are formed in each of the injectors 131 to 133.

The plurality of injectors 131 to 133 are installed such that each of the injectors 131 to 133 is connected to each of the plurality of mass flow controllers 171 to 173 of the vaporization raw material supplying device 250 on a one-to-one basis. Therefore, flow rates of the injectors 131 to 133 can be controlled by the respective mass flow controllers 171 to 173. In the example of FIG. 1, the injector 131 is connected to the mass flow controller 171, the injector 132 is connected to the mass flow controller 172, and the injector 133 is connected to the mass flow controller 173.

In FIG. 1, the plurality of injectors 131 to 133 are installed respectively in different regions defined inside the processing vessel 1 so as to supply the vaporization raw material to the different regions on the wafer W. In the configuration of the substrate processing apparatus 300 including the process container 1 and the like, there may be a case where a substrate process applied to a specific region on the wafer W is insufficient or excessive. In such a case, by setting different flow rates of the vaporization raw material for respective regions, it is possible to correct the insufficient or excessive substrate process, thus performing the substrate process with higher uniformity over the entire surface of the wafer W. The vaporization raw material supplying device and the substrate processing apparatus according to the present embodiment are very suitable for performing the flow rate adjustment described above.

In FIG. 1, Magnitudes of the flow rates are schematically represented by the sizes of arrows. A description will be made to a case in which the flow rate from the injector 133 positioned at the left side is set to the smallest, the flow rate from the injector 131 positioned at the right side is set to the largest and the flow rate from the injector 132 positioned at the center is set to an intermediate value between the smallest and largest values as shown in FIG. 1.

In this case, naturally, the flow rate setting value of the mass flow controller 173 connected to the injector 133 is the smallest, and the flow rate setting value of the mass flow controller 171 connected to the injector 131 is the largest. The flow rate setting value of the mass flow controller 172 connected to the injector 132 is an intermediate value between the smallest and largest values. Here, even if the flow rate set in each of the injectors 131 to 133 is changed, it is possible to change the set flow rate to an arbitrary flow rate since the flow rates of the injectors 131 to 133 are individually controlled by the respective mass flow controllers 171 to 173. As described above, in the case where one injector is installed and the arrangement or sizes of the gas injection holes are differently set in the respective regions, a change in the set flow rate causes collapse of a relationship between the respective regions, resulting in an insufficient response to the change in the flow rate. However, the vaporization raw material supplying device 250 and the substrate processing apparatus 300 according to the present embodiment can cope with the change in the flow rate without causing any problem.

Further, even in a case Where a problem occurs in the accuracy of the gas injection holes 151 to 153 of the injectors 131 to 133 so that a flow rate ratio in the respective regions is not obtained as designed, the vaporization raw material supplying device 250 and the substrate processing apparatus 300 according to this embodiment can control flow rates of the vaporization raw material supplied through the gas injection holes 151 to 153, which are ultimate outputs. Thus, no problem occurs.

Furthermore, even when clogging or the like occurs in the gas injection holes 151 to 153 so that the flow rates are changed, the mass flow controllers 171 to 173 adjust the respective flow rates as the ultimate outputs such that the respective flow rates become constant. Thus, it is possible to cope with such changes over time without causing any problem.

As described above, by installing the mass flow controllers 171 to 173 to correspond respectively to the injectors 131 to 133 installed in the multiple channels, it is possible to flexibly cope with various changes and to supply the vaporization raw material at desired flow rates.

Although in FIG. 1, an example in which the injectors has been illustrated to be installed in three channels, other multiple channels may be used depending on the intended use.

Further, although in FIG. 1, the plurality of injectors 131 to 133 has been described to be installed without a region overlapping with one another and to supply the vaporization raw material to different regions, the present disclosure is not limited thereto. As an example, the plurality of injectors 131 to 133 may be arranged such that adjacent regions are partially overlapped with one another.

Moreover, although in FIG. 1, the components of the substrate processing apparatus 300 are illustrated at a minimum level, the substrate processing apparatus 300 may include various components required for the substrate process, such as a mounting table on which the wafer W is mounted, an evacuation means for evacuating the interior of the process container 1 and the like, if necessary.

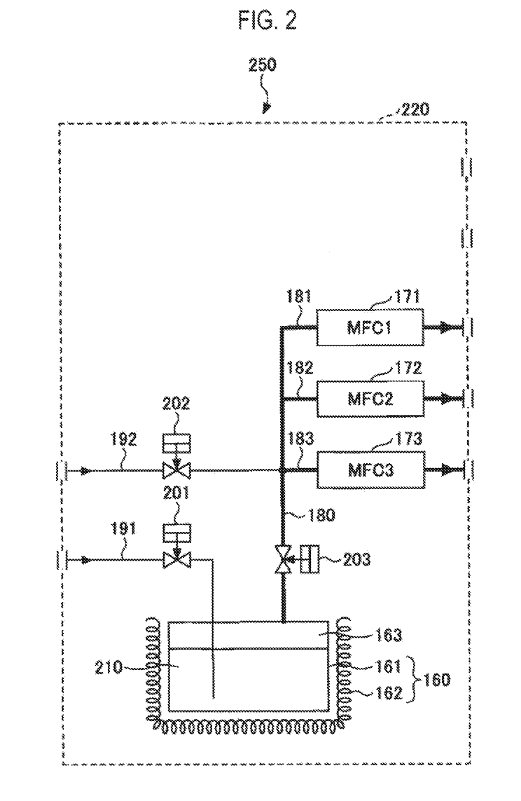

Next, a configuration of the vaporization raw material supplying device 250 will be described in more detail with reference to FIG. 2. FIG. 2 is a view illustrating one more specific example of the vaporization raw material supplying device 250.

A configuration shown, in FIG. 2 is similar to that of FIG. 1 in that the heating tank 160, the plurality of mass flow controllers 171 to 173, the main pipe 180 and the branch pipes 181 to 183 are housed in the casing 220 except that a raw material pipe 191, a purge pipe 192 and valves 201 to 203 are installed inside the casing 220.

The raw material pipe 191 is to supply the raw material 210 to the heating tank 160. If the raw material 210 is a liquid raw material, it is possible to supply the raw material 210 into the heating tank 160 using the raw material pipe 191. An example in which 3DMAS is used as the raw material 210 is shown in FIG. 2. In addition, the valve 201 is to perform opening/closing and flow rate adjustment of the raw material pipe 191.

The purge pipe 192 is a pipe used in supplying a purge gas to the main pipe 180 and the branch pipes 181 to 183 to clean them when the vaporization raw material is not being supplied to the process container 1. A nobble gas such as argon (Ar) gas or helium (He) gas, or an inert gas such as a nitrogen (N₂) gas may be used as the purge gas depending on an intended use. In FIG. 2, an example in which the nitrogen (N₂) gas is used as the purge gas is shown. Moreover, the valve 202 is to perform an opening/closing and flow rate adjustment of the purge pipe 192. The valve 202 is opened when the substrate process is being performed. The valve 202 is closed when the substrate process is completed and the vaporization raw material is not being supplied to the process container 1.

The valve 203 is to perform an opening/closing and flow rate adjustment of the main pipe 180. The valve 203 is opened when the vaporization raw material is supplied from the heating tank 160 to the mass flow controllers 171 to 173, i.e., when the substrate process is being performed. The valve 203 is closed when the substrate process is on standby or under suspension.

The valves 201 to 203 may be manual valves or electromagnetic valves. In some embodiments, the valves 201 to 203 may be the electromagnetic valves or air-operated valves such that they can be handled from the outside of the casing 220.

Other components are the same as those described with reference to FIG. 1. Accordingly, the same components will be designated by like reference numerals with the descriptions thereof omitted.

### Second Embodiment

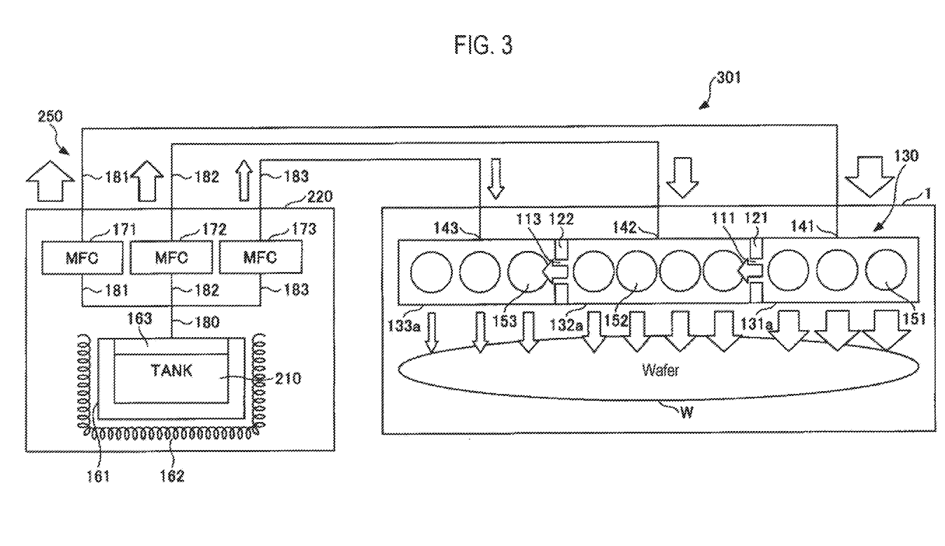

FIG. 3 is a view showing an example of a substrate processing apparatus 301 according to a second embodiment of the present disclosure. A vaporization raw material supplying device 250 is the same as the vaporization raw material supplying device 250 according to the first embodiment. Accordingly, the same components will be designated by like reference numerals with the descriptions thereof omitted.

In the substrate processing apparatus 301 according to the second embodiment, a configuration of an injector 130 is different from that of the plurality of injectors 131 to 133 according to the first embodiment. In the substrate processing apparatus 301 according to the second embodiment, the single injector 130 is used in place of the plurality of injectors 131 to 133. A plurality of partition walls 121 and 122 are installed in the single injector 130 to divide the interior of the injector 130 into three chambers 131a to 133a. Further, orifices 111 and 112 are respectively formed in the partition walls 121 and 122 so that the three chambers 131a to 133a are in communication with one another

As in the first embodiment, a description will be made as to an example in which the vaporization raw material is supplied to the chamber 133a at a minimum flow rate, to the chamber 131a at a maximum flow rate, and to the chamber 132a at an intermediate flow rate between the minimum and maximum flow rates.

In this case, naturally, the vaporization raw material is supplied to the chambers 131a to 133a at different flow rates through the respective mass flow controllers 171 to 173. The orifice 111 is formed in the partition wall 121 by which the chambers 131a and 132a are partitioned, and the orifice 122 is formed in the partition wall 122 by which the chambers 132a and 133a are partitioned. Thus, the vaporization raw material flowing into the chamber 131a can flow into the chamber 132a via the orifice 111, and the vaporization raw material flowing into the chamber 132a can flow into the chamber 133a via the orifice 112. Therefore, the vaporization raw material injected from the gas injection holes 151 to 153 is supplied with flow rates there smoothly distributed over all the regions, without changing in a stepped pattern over the three regions. Downwardly-oriented arrows below the gas injection holes 151 to 153 in FIG. 3 schematically represent the smooth distribution of the flow rates, in other words, the vaporization raw material is introduced into gas inlet holes 141 to 143 at three predetermined levels of flow rates as indicated by three arrows. Ultimately, the vaporization raw material is injected from the plurality of gas injection holes 151 to 153 at more smooth flow rate ratios as indicated by ten levels of arrows.

As described above, according to the substrate processing apparatus 301 of the second embodiment, by partitioning the interior of the single injector 130 into the chambers 131a to 133a corresponding to the three regions by the partition walls 121 and 122,and by forming the orifices 111 and 112 functioning as communication holes in the partition walls 121 and 122, it is possible to supply the vaporization raw material to the water W at flow rates whose differences therebetween are uniform.

### Third Embodiment

In the following embodiment, a description will be made to an example in which the vaporization raw material supplying device 250 and the substrate processing apparatuses 300 and 301 described in the first and second embodiments are applied to a more specific substrate processing apparatus. A substrate processing apparatus 302 according to a third embodiment is configured as an ALD (atomic layer deposition) film forming apparatus and is an apparatus configured to perform a film formation process using the ALD method.

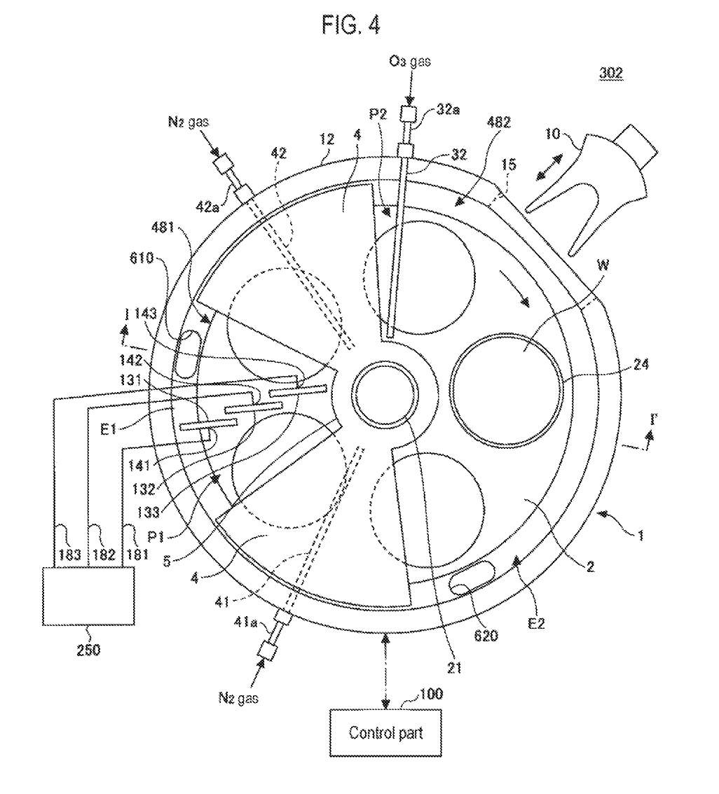

FIG. 4 is a view showing an example of the substrate processing apparatus 302 according to the third embodiment of the present disclosure. An internal structure of a process container 1 of the substrate processing apparatus 302 is shown in FIG. 4. In addition, the shape of the process container 1 according to the third embodiment is the same as that of the process container 1 of the substrate processing apparatuses 300 and 301 according to the first and second embodiments and therefore the process container will be designated by like reference numerals.

In FIG. 4, there is shown a container main body 12 constituting a lateral surface and an internal bottom surface of the process container I in a state where a ceiling plate is removed from the process container 1. A disc-shaped rotary table 2 is installed above the internal bottom surface of the container main body 12.

As shown in FIG. 4, a plurality of circular recesses 24 on which a plurality of wafers W (five wafers W in this example) is mounted, is formed in a surface of the rotary table 2 in a rotational direction (a circumferential direction) of the rotary table 2. In FIG. 4, one sheet of the water W is mounted on only one of the recesses 24 for the sake of convenience. The recess 24 has an inner diameter that is slightly greater than a diameter (for example, 300 mm) of the wafer W, by, for example, 4 mm, and a depth substantially equal to a thickness of the wafer W. Thus, if the wafer W is mounted in the recess 24, a surface of the wafer W is flush with the surface of the rotary table 2 (a region in which the wafer W is not mounted).

The injectors 131 to 133, a reaction gas nozzle 32 and separation gas nozzles 41 and 42, which are made of, for example, quartz, are arranged above the rotary table 2. In the example of FIG. 4, the separation gas nozzle 41, the injectors 131 to 133, the separation gas nozzle 42 and the reaction gas nozzle 32 are arranged in this order from a transfer port 15 (to be described later) in a clockwise direction (the rotation direction of the rotary table 2) at certain intervals along a circumferential direction of the process container 1. The injectors 131 to 133 are separately and independently installed in the plurality of regions as described in the first embodiment. In FIG. 4, in a radial direction of the rotary table 2, the injector 131 is installed in a region of an outer peripheral side of the rotary table 2, the injector 133 is installed in a region of a central side (inner side) of the rotary table 2, and the injector 132 is installed in a region of a middle side of the rotary table 2. With the rotation of the rotary table 2, the wafer W mounted on the rotary table 2 moves along the rotation direction. The vaporization raw material is injected from the gas injection holes 151 to 153 of the injectors 131 to 133 such that the vaporization raw material is sequentially supplied onto surfaces of the plurality of wafers W (five wafers W in FIG. 4). Thus, the entire diameter of the wafer W is covered by the injectors 131 to 133 so that the vaporization raw material is supplied onto the entire surface of the wafer W. The injectors 131 to 132 basically cover the different regions of the outer peripheral side, the middle side and the central side in the radial direction of the rotary table 2 without overlapping with one another. However, end portions of the adjacent injectors 131 and 132 overlap with each other and end portions of the adjacent injectors 132 and 133 overlap with each other. By forming such overlapped portions, it is possible to supply the vaporization raw material onto the entire surface of the wafer W, without causing a region to which the vaporization raw material is not supplied.

The supply of the vaporization raw material to the injectors 131 to 133 is performed by supplying the vaporization raw material from the vaporization raw material supplying device 250 to the gas inlet holes 141 to 143 via the branch pipes 181 to 183, respectively. As shown in FIGS. 1 and 3, the branch pipes 181 to 183 are introduced through the upper face of the process container 1, and the vaporization raw material is introduced into the respective gas inlet holes 141 to 143 of the injectors 131 to 133.

When the rotary table 2 is rotated, a movement distance at the outer peripheral side of the rotary table 2 is larger than that at the central side thereof. Thus, a movement speed at the outer peripheral side is higher than that at the central side. As such, there may be a case where a time for adsorption of the vaporization raw material onto the wafer W at the outer peripheral side of the rotary table 2 is insufficient. In this regard, there may be a case where a flow rate at the outer peripheral side is set larger than that at an inner peripheral side. Even in the present embodiment, an example in which the flow rates of vaporization raw material in the injector 131, the injector 132 and the injector 133 are set to be increased in this order so as to meet the aforementioned tendency is described.

The gas introduction ports 32a, 41a and 42a, which are base end portions of the nozzles 32, 41, and 42 other than the injectors 131 to 133, are fixed to an outer peripheral wall of the container main body 12, so that the nozzles 32, 41, and 42 are introduced from the outer peripheral wall of the process container 1 into the process container 1 and are installed to extend in parallel to the rotary table 2 in a radial direction of the container main body 12.

Each of the nozzles 32, 41 and 42 is connected to a gas supply source and a mass flow controller (if necessary), and various gases may be supplied to the nozzles 32, 41 and 42 depending on processes.

For example, in order to oxidize 3DMAS to generate SiO₂, a supply source (not shown) configured to supply an ozone (O₃) gas may be connected to the reaction gas nozzle 32 via an opening/closing valve and a flow rate adjuster (both not shown).

In addition, a supply source configured to supply an inert gas such as a nobble gas such as an Ar gas, a He gas or the like, a nitrogen (N₂) gas or the like, may be connected to each of the separation gas nozzles 41 and 42 via an opening/closing valve and a mass flow controller (both not shown). In FIG. 4, an example in which the N₂ gas is used as the inert gas is shown.

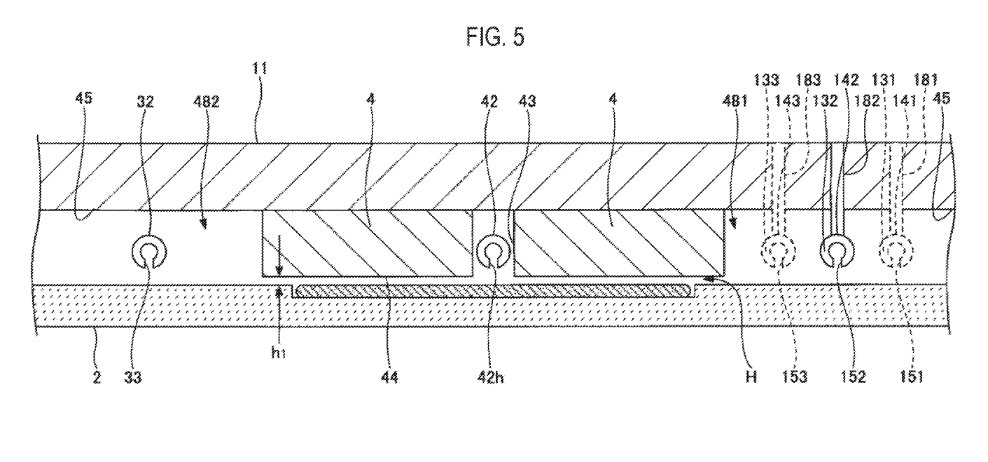

FIG. 5 is a view showing a cross-section of the process container 1 in a concentric relationship with the rotary table 2 from the injectors 131 to 133 to the reaction gas nozzle 32. As shown in FIG. 5, the branch pipes 181 to 183 penetrating through a ceiling plate 11 of the process container 1 are respectively connected to the injectors 131 to 133, and the vaporization raw material is supplied to each of the gas inlet holes 141 to 143. The gas injection holes 151 to 153 are formed in lower surfaces of the respective injectors 131 to 133.

Further, a plurality of gas injection holes 33 opened downwardly toward the rotary table 2 is formed in the reaction gas nozzle 32 to be arranged in a longitudinal direction of the reaction gas nozzle 32. A region below the injectors 131 to 133 is defined as a first process region P1 in which the vaporization raw material such as the 3DMAS gas or the like is adsorbed onto the wafer W. A region below the reaction gas nozzle 32 is defined as a second process region P2 in which the vaporization raw material adsorbed onto the wafer W in the first process region P1 is oxidized.

Referring to FIGS. 4 and 5, two projected portions 4 are formed inside the process container 1. Each of the projected portions 4 has a substantially fan-like planar shape with the apex portion thereof cut in an arc shape. In the present embodiment, an inner arc portion of the projected portion 4 is connected to a protrusion 5 (to be described later and an outer arc portion thereof is disposed to conform to an inner peripheral surface of the container main body 12 of the process container 1. As shown in FIG. 5, the projected portions 4 are attached to a back surface of the ceiling plate 11. Thus, flat low ceiling surfaces 44 (first ceiling surfaces) as lower surfaces of the projected portions 4, and a ceiling surface 45 (a second ceiling surface), which is higher than the ceiling surfaces 44 and placed at both sides of the first ceiling surfaces 44 in a circumferential direction, are formed within the process container 1.

In addition, as shown in FIG. 5, a groove portion 43 is formed at the central side in the circumferential direction. The groove portion 43 extends in the radial direction of the rotary table 2. The separation gas nozzle 42 is accommodated in the groove portion 43. Similarly, another groove portion 43 is formed in the other projected portion 4 and the separation gas nozzle 41 is accommodated in the respective groove portion 43. Further, gas injection holes 42h are formed in the separation gas nozzle 42.

The injectors 131 to 133 and the reaction gas nozzle 32 are arranged in spaces below the second ceiling surface 45, respectively. The injectors 131 to 133 and the reaction gas nozzle 32 are arranged in the vicinity of the wafer W while being spaced apart from the second ceiling surface 45.

A separation space H as a narrow space is formed between the first ceiling surfaces 44 and the rotary table 2. When the N₂ gas is supplied from the separation gas nozzle 42, the N₂ gas flows toward spaces 481 and 482 through the separation space H. At this time, since the volume of the separation space H is smaller than those of the spaces 481 and 482, a pressure of the separation space H may be higher than those in the spaces 481 and 482 due to the N₂ gas. In other words, the separation space H functions as a pressure barrier between the spaces 481 and 482. Therefore, the vaporization raw material such as 3DMAS supplied from the first process region P1 and the O₃ gas supplied from the second process region P2 are separated by the separation space H. This suppresses the vaporization raw material and the O₃ gas from being mixed and reacted with each other within the process container 1.

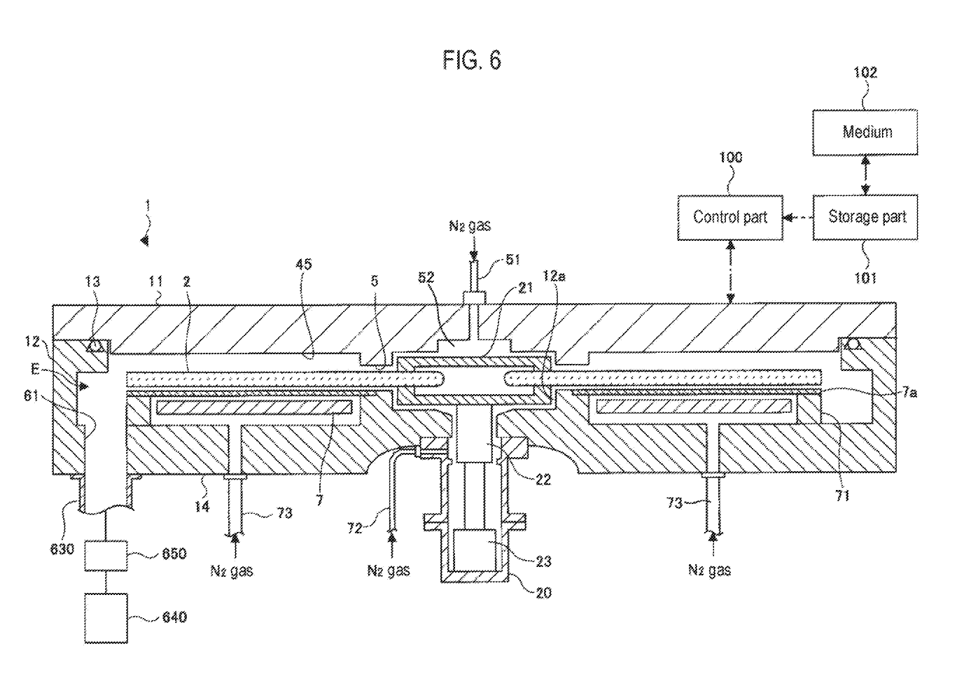

FIG. 6 is a cross-sectional view taken along line I-I′ in FIG. 4, which shows a region in which the second ceiling surface 45 is formed.

As shown in FIG. 6, the substrate processing apparatus 302 includes the flat process container 1 having a substantially circular planar shape, and the rotary table 2 installed inside the process container 1 and having a rotational center at the center of the process container 1. The process container 1 includes the container main body 12 of a cylindrical shape with a bottom surface, and the ceiling plate 11 hermetically and detachably installed on an upper face of the container main body 12 through a seal member 13 (in FIG. 6) such as an O-ring or the like.

The rotary table 2 is fixed to a cylindrical core portion 21 at the central portion of the rotary table 2. The core portion 21 is fixed to an upper end of a rotational shaft 22 extending in a vertical direction. The rotational shaft 22 penetrates through a bottom portion 14 of the process container 1. A lower end of the rotational shaft 22 is attached to a driving part 23 configured to rotate the rotational shaft 22 (FIG. 6) around a vertical axis. The rotational shaft 22 and the driving part 23 are accommodated in a tubular case body 20 with an opened top face. A flange portion formed in an upper face of the case body 20 is hermetically attached to a lower surface of the bottom portion 14 of the process container 1 such that an internal atmosphere of the case body 20 is isolated from an external atmosphere.

A first exhaust port 610 communicating with the space 481 and a second exhaust port 620 communicating with the space 482 are formed between the rotary table 2 and the inner peripheral surface of the container main body 12. As shown in FIG. 6, the first exhaust port 610 and the second exhaust port 620 are coupled to a vacuum pump 640as a vacuum-exhaust means via an exhaust pipe 630, respectively. In addition, a pressure regulator 650 is installed in the exhaust pipe 630.

As shown in FIG. 6, a heater unit 7 functioning as a heating means is installed in a space between the rotary table 2 and the bottom portion 14 of the process container 1. The wafer W mounted on the rotary table 2 is heated through the rotary table 2 to a temperature (for example, 450 degrees C.) determined according to a process recipe. A ring-shaped cover member 71 is installed below and near the outer periphery of the rotary table 2 in order to prevent a gas from entering the space below the rotary table 2.

As shown in FIG. 6, in the bottom portion 14 of the process container, an upwardly-protruded portion 12a is formed in the vicinity of the rotational center from the space where the heater unit 7 is disposed such that the upwardly-protruded portion 12a is positioned near the core portion 21 in the vicinity of the central portion of the lower surface of the rotary table 2. A narrow space is formed between the upwardly-protruded portion 12a and the core portion 21. In addition, a narrow gap is formed between an inner peripheral surface of a through hole formed to penetrate through the bottom portion 14 and the rotational shaft 22 installed to pass through the through hole. The narrow space is in communication with the case body 20. Moreover, in the case body 20, a purge gas supply pipe 72 configured to supply the N₂ gas as a purge gas into the narrow space to purge the interior of the case body 20. Further, in the bottom portion 14 of the process container 1, a plurality of purge gas supply pipes 73 configured to purge the space where the heater unit 7 is installed is installed below the heater unit 7 at predetermined angular intervals in the circumferential direction (two purge gas supply pipe 73 are shown in FIG. 6).

Further, a separation gas supply pipe 51 is connected to a central portion of the ceiling plate 11 of the process container 1 so as to supply a N₂ gas as a separation gas into a space 52 between the ceiling plate 11 and the core portion 21.

Further, as shown in FIG. 4, the transfer port 15 used in transferring the wafer W as a substrate between an external transfer arm 10 and the rotary table 2 is formed in a sidewall of the process container 1.

Moreover, as shown in FIG. 6, the substrate processing apparatus 302 according to the present embodiment is provided with a control part 100 including a computer configured to control the entire operations of the apparatus. A program for executing a film forming method (to be described later) in a film forming apparatus under the control of the control part 100 is stored in a memory of the control part 100. This program is stored in a medium 102 such as a hard disk, a compact disk, a magneto-optical disk, a memory card, a flexible disk or the like. The program is read in a storage part 101 by a certain reading device and is installed into the control part 100.

As described above, the vaporization raw material supplying device 250 can be used for the substrate processing apparatus 302 that performs the film formation process. It is therefore possible to accurately control the flow rates of the vaporization raw material to be supplied to the respective regions inside the process container 1 in which the injectors 131 to 133 are installed, thus performing the film formation process with good in-plane uniformity.

### Fourth Embodiment

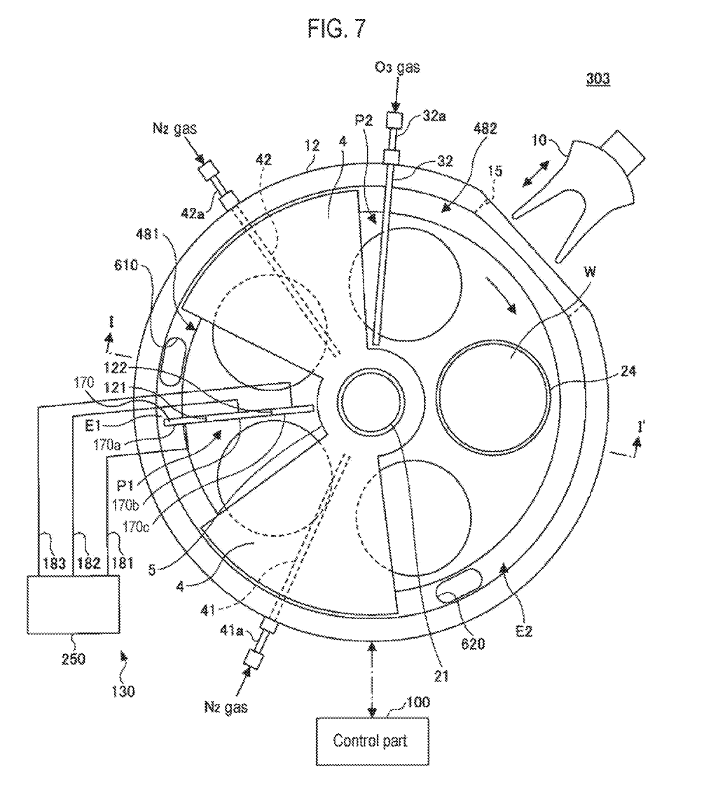

FIG. 7 is a view showing an example of a substrate processing apparatus 303 according to a fourth embodiment of the present disclosure. In FIG. 7, a single injector 170 is connected to the vaporization raw material supplying device 250. The injector 170 includes three chambers 170a, 170b and 170c as three regions.

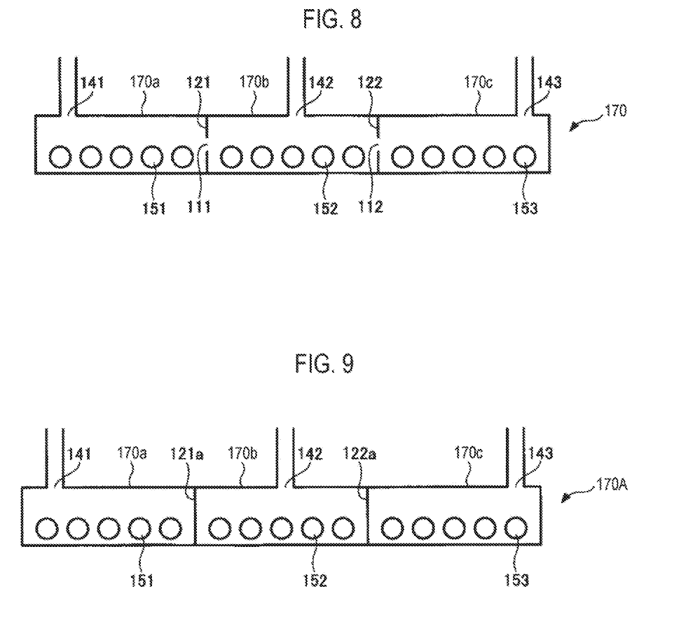

FIG. 8 is a lateral cross-sectional view of the injector 170. As shown in FIG. 8, the interior of the injector 170 is divided by the partition walls 121 and 122 into three chambers 170a, 170b and 170c. Orifices 111 and 112 functioning as communicating holes are respectively formed in the partition walls 121 and 122 such that the chambers 170a, 170b and 170c are in communication with each other. That is to say, this embodiment is an example in which the substrate processing apparatus 301 according to the second embodiment is applied to a specific apparatus. As described above, according to the substrate processing apparatus 303 according to the fourth embodiment, it is possible to supply the vaporization raw material to the respective regions inside the process container 1 with a smooth flow rate distribution, thereby performing the ALD film forming process.

Other components are the same as those of the substrate processing apparatus 302 according to the third embodiment, and therefore a description thereof is omitted.

### Fifth Embodiment

FIG. 9 is a view showing an example of an injector 170A of a substrate processing apparatus according to a fifth embodiment of the present disclosure. The substrate processing apparatus according to the fifth embodiment has the same planar configuration as the substrate processing apparatus 303 according to the fourth embodiment shown in FIG. 7 except that a configuration of the injector 170A is different from that of the injector 170 according to the fourth embodiment.

The injector 170A of the substrate processing apparatus according to the fifth embodiment is different from the injector 170 of the substrate processing apparatus 303 according to the fourth embodiment in that, as shown in FIG. 9, no orifice is formed in partition walls 121a and 122a and chambers 170a to 170c are completely separated from each other.

As described above, the chambers 170a to 170c may be completely separated from one another by not installing the orifices 111 and 112 in the partition walls 121a and 122a. With this configuration, it is possible to install the injector 170A in a space-saving manner and at low costs as compared with the case where three independent injectors 131 to 133 are installed.

Other components are the same as those of the substrate processing apparatuses 302 and 304 according to the third and fourth embodiments, and therefore a description thereof is omitted.

### Sixth Embodiment

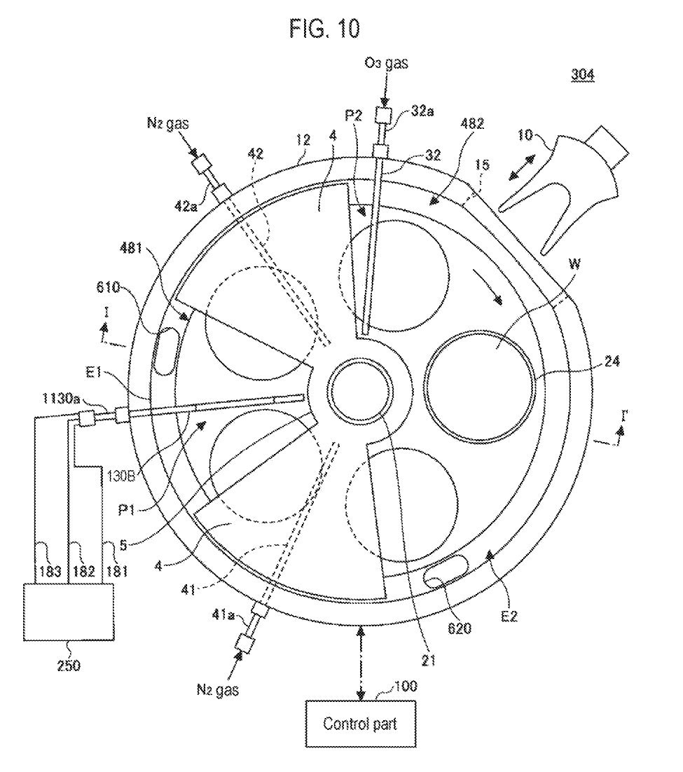

FIG. 10 is a view showing an example of a substrate processing apparatus 304 according to a sixth embodiment of the present disclosure. The substrate processing apparatus 304 according to the sixth embodiment is the same as the substrate processing apparatuses 303 according to the fourth and fifth embodiments in that a single injector 130B is installed. However, the substrate processing apparatus 304 according to the sixth embodiment is different from the substrate processing apparatuses 303 according to the fourth and fifth embodiments in that a single gas introduction port 1130 is installed in an outer periphery of the container main body 12.

In this case, the vaporization raw material is supplied from the single gas introduction port 1130. The injector 130B is configured to be introduced from the outer peripheral wall of the container main body 12 into the process container 1 and to horizontally extend from an outer peripheral side toward a central side in parallel to the rotary table 2.

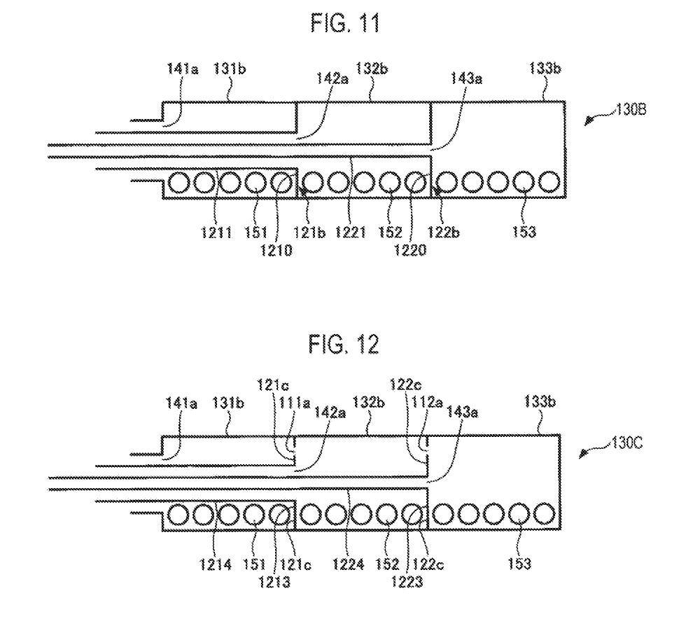

FIG. 11 is a view illustrating a cross-sectional configuration of an example of the injector 130B. As shown in FIG. 11, partition walls 121b and 122b of the injector 130B include portions 1210 and 1220 that are disposed perpendicular to a longitudinal direction of the injector 130B to divide the interior of the injector 130B into chambers 131b to 133b in the longitudinal direction, and portions 1211 and 1221 that extend in the longitudinal direction and have a configuration of a concentric pipe such as a triple pipe to divide the respective chambers 131b to 133b in a diameter direction of the injector 130B. Through such a configuration, gas inlet openings 141a to 143a of the respective chambers 131b to 133b are formed to be displaced in the longitudinal direction of the injector 130B. Thus, these gas inlet openings 141a to 143a are formed at different positions in the longitudinal direction. Specifically, the gas inlet opening 143a of the chamber 133b located at a right innermost side (tip side) is formed to be displaced inward of the right side, the gas inlet opening 142a of the chamber 132b is formed to be slightly displaced to the left side (entrance side) from the center of the injector 130B, and the gas inlet opening 141a of the chamber 132b located near the entrance side is formed at the entrance side through which the entire inlet holes of the injector 130B pass.

As described above, the interior of the injector 1303 may be configured to have a structure of the triple pipe through the use of the partition walls 121b and 122b having the portions 1211 and 1221 of a concentric tubular shape. In this case, similarly to other nozzles 32, 41 and 42, it is possible to introduce the vaporization raw material from the outer peripheral wall of the container main body 12.

Other components are the same as those of the substrate processing apparatuses 302 and 303 according to the third to fifth embodiments, and therefore descriptions thereof are omitted.

### Seventh Embodiment

FIG. 12 is a view showing an example of an injector 130C of a substrate processing apparatus according to a seventh embodiment. The substrate processing apparatus according to the seventh embodiment has the same planar configuration as the substrate processing apparatus 304 according to the sixth embodiment shown in FIG. 10, except that a configuration of the injector 130C is different from that of the injector 130B of the substrate processing apparatus 304.

As shown in FIG. 12, the injector 130C of the substrate processing apparatus according to the seventh embodiment is the same as the injector 130B of the substrate processing apparatus 304 according to the sixth embodiment in that partition walls 121c and 122c of the injector 130C include portions 1213 and 1223 that divide the interior of the injector 130C into chambers 131b to 133b in the longitudinal direction, and portions 1214 and 1224 that extend in the longitudinal direction to have a configuration of a concentric pipe such as a triple pipe and divide the respective chambers 131b to 133b in a diameter direction of the injector 130C. However, the injector 130C of the substrate processing apparatus according to the seventh embodiment is different from the injector 130B of the substrate processing apparatus 304 according to the sixth embodiment in that orifices 111a and 112a are formed in the portions 1213 and 1223 of the partition walls 121c and 122c extending in the diameter direction such that the chambers 131b to 133b are in communication with one another.

As described above, the chambers 131b to 133b may be configured to be in communication with one another by respectively forming the orifices 111a and 112a in portions of the partition walls 121c and 122c. With this configuration, it is possible to configure the injector 130C in a space-saving manner and at low costs as compared with the case where three independent injectors 131c to 133c are installed. Further, it is possible to smoothly distribute injection amounts of the vaporization raw material injected from the gas injection holes 151 to 153, thus controlling flow rates with a high degree of accuracy. Further, the orifices 111a and 112a may be formed at any position as long as the chambers 131b to 133b are configured to communicate with one another.

Other components are the same as those of the substrate processing apparatuses 302, 303 and 304 according to the third to sixth embodiments, and therefore descriptions thereof are omitted.

### Eighth Embodiment

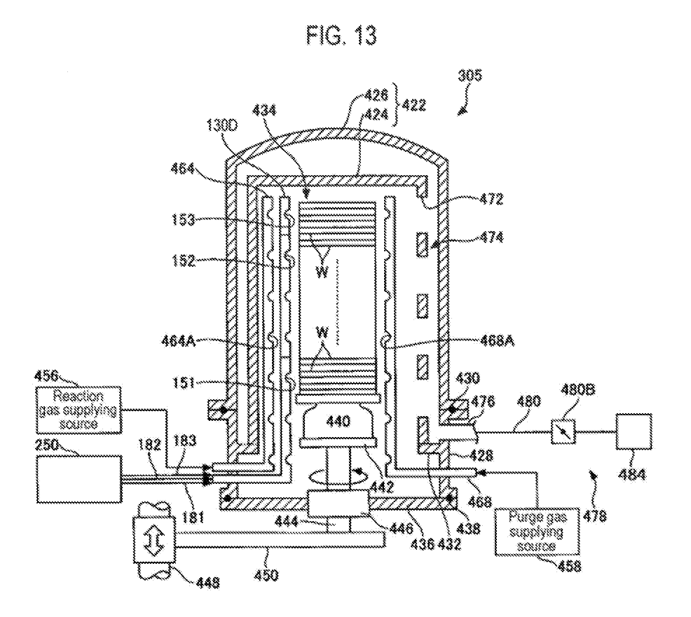

FIG. 13 is a view showing an example of a substrate processing apparatus according to an eighth embodiment. A substrate processing apparatus 305 according to the eighth embodiment will be described with an example in which the vaporization raw material supplying apparatus 250 is applied to a vertical type heat treatment apparatus.

FIG. 13 shows an overall configuration illustrating an example of the substrate processing apparatus 305 according to the eighth embodiment of the present disclosure. As shown in FIG. 13, the substrate processing apparatus 305 includes a process container 422 capable of accommodating a plurality of wafers W. The process container 422 is composed of a vertically-elongated cylindrical inner tube 424 with a ceiling and a vertically-elongated cylindrical outer tube 426 with a ceiling. The outer tube 426 is disposed to surround the inner tube 424 with a predetermined gap between an outer periphery of the inner tube 424 and an inner periphery of the outer tube 426. In addition, all the inner and outer tubes 424 and 426 are made of, for example, quartz.

A cylindrical manifold 428 made of, for example, stainless steel is hermetically connected to a lower end portion of the outer tube 426 via a sealing member 430 such as an O-ring so that the lower end portion of the outer tube 426 is supported by the manifold 428. The manifold 428 is supported by a base plate (not shown). Further, a ring-shaped support member 432 is formed in an inner wall of the manifold 428, so that a lower end portion of the inner tube 424 is supported by the support member 432.

A wafer boat 434 as a wafer holding part is accommodated in the inner tube 424 of the process container 422. The plurality of waters W is held at predetermined pitches in the water boat 434. In the present embodiment, for example, approximately 50 to 100 sheets of wafers W having a diameter of 300 mm are held in multiple stages by the wafer boat 434 at a substantially equal pitch. The wafer boat 434 can be moved up and down so that the wafer boat 434 is loaded into the inner tube 424 from below the process container 422 through a lower opening of the manifold 428 or is unloaded from the inner tube 424. The wafer boat 434 is made of, for example, quartz.

Further, when the wafer boat 434 is loaded, the lower opening of the manifold 428, which is a lower end of the process container 422, is closed by a cover part 436 made of, for example, a quartz or stainless steel plate. A seal member 438 such as an O-ring is interposed between the lower end portion of the process container 422 and the cover part 436 in order to maintain airtightness. The wafer boat 434 is placed on a table 442 via a heat-insulating tube 440 made of quartz. The table 442 is supported by an upper end portion of a rotational shaft 444 which passes through the cover part 436 for opening/closing the lower opening of the manifold 428.

For example, a magnetic fluid seal 446 is installed between the rotational shaft 444 and a hole of the cover part 436 through which the rotational shaft 444 passes, so that the rotational shaft 444 is rotatably supported while being hermetically sealed. The rotational shaft 444 is installed in a tip of an arm 450 supported by an elevation mechanism 448 such as a boat elevator or the like, so that the wafer boat 434, the cover part 436 and the like can be integrally raised and lowered. In some embodiments, the table 442 may be fixedly installed to the cover part 436 side to perform a film formation process on the wafers W without rotating the wafer boat 434.

Moreover, a heating part (not shown composed of, for example, a carbon wire-made heater and formed to surround the process container 422 is installed at a lateral side of the process container 422. Thus, the process container 422 located inside this heating part and the wafers W accommodated in the process container 422 are heated.

In addition, the vaporization raw material supplying device 250 configured to supply the vaporization raw material, a reaction gas supplying source 456 configured to supply a reaction gas and a purge gas supplying source 458 configured to supply an inert gas as a purge gas are installed in the substrate processing apparatus 305.

The vaporization raw material supplying device 250 stores and vaporizes a liquid (or solid) raw material such as 3DMAS, and is coupled to an injector 130D via a main pipe 180 in which mass flow controllers 171 to 173 and opening/closing valves 191 to 193 are installed, and branch pipes 181 to 183. The injector 130D hermetically passes through the manifold 428, is bent in an L-shape within the process container 422 and then extends over an entire vertical region within the inner tube 424. A plurality of gas injection holes 151 to 153 is formed in the injector 130D at a predetermined pitch so that a raw material gas can be horizontally supplied to the wafers W supported by the wafer boat 434. The injector 130D may be made of, for example, quartz.

The reaction gas supplying source 456 stores, for example, an ammonia (NH₃) gas and is coupled to a gas nozzle 464 via a pipe in which a mass flow controller and an opening/closing valve (not shown) are installed. The gas nozzle 464 hermetically passes through the manifold 428, is bent in an L-shape within the process container 422 and then extends over the entire vertical region within the inner tube 424. A plurality of gas injection holes 464A is formed in the gas nozzle 464 at a predetermined pitch so that a reaction gas can be horizontally supplied to the wafers W supported by the wafer boat 434. The gas nozzle 464 may be made of, for example, quartz.

The purge gas supplying source 458 stores the purge gas and is coupled to a gas nozzle 468 via a pipe in which a mass flow controller and an opening/closing valve (not shown) are installed. The gas nozzle 468 hermetically passes through the manifold 428, is bent in an shape within the process container 422 and then extends over the entire vertical region within the inner tube 424. A plurality of gas injection holes 468A is formed in the gas nozzle 468 at a predetermined pitch so that the purge gas can be horizontally supplied to the wafers W supported by the wafer boat 434. The gas nozzle 468 may be made of, for example, quartz. In addition, a nobble gas such as an Ar gas, a He gas or the like, or an inert gas such as a nitrogen gas or the like may be used as the purge gas.

The injector 130D and the respective gas nozzles 464 and 468 are collectively installed at one side in the inner tube 424 (in the illustrated example, the gas nozzle 468 is shown as being installed at a side opposite to the injector 130D and the gas nozzles 464 due to a small space in FIG. 13). A plurality of gas circulation holes 472 is formed to be arranged in a vertical direction in a sidewall opposite to the injector 130D and the gas nozzles 464 and 468 in the inner tube 424. Thus, the gases supplied from the injector 1301) and the gas nozzles 464 and 468 horizontally flow between the wafers W and are guided into a gap 474 between the inner tube 424 and the outer tube 426 through the gas circulation holes 472.

An exhaust port 476 communicating with the gap 474 between the inner tube 424 and the outer tube 426 is formed above the manifold 428. The exhaust port 476 is connected to an exhaust system 478 configured to exhaust the process container 422.

The exhaust system 478 includes a pipe 480 connected to the exhaust port 476. A pressure regulating valve 480B and a vacuum pump 484 are sequentially installed in the pipe 480. The pressure regulating valve 480B is configured to adjust an opening degree of a valve body thereof. The pressure regulating valve 480B adjusts an internal pressure of the process container 422 by changing the opening degree of the valve body. Accordingly, it is possible to exhaust an internal atmosphere of the process container 422 down to a predetermined pressure while adjusting the internal pressure.

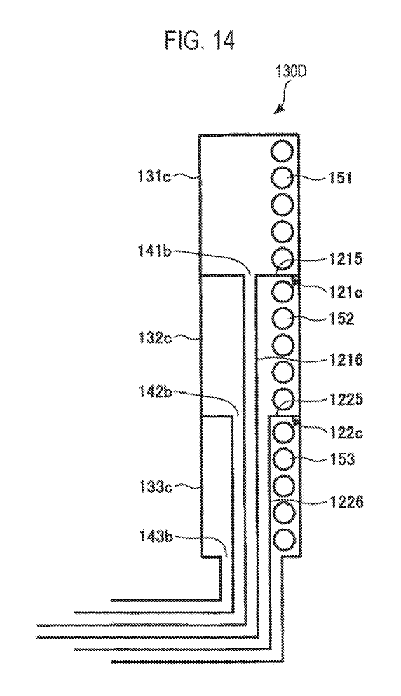

FIG. 14 is a cross-sectional view showing a configuration of an example of the injector 130D. As shown in FIG. 14, an interior of the vertically-elongated injector 130D is divided into three chambers 131c to 133c by partition walls 121c and 122c. No orifice is formed in the partition walls 121c and 122c so that the respective chambers 131c to 133c are completely separated from one another. The partition walls 121c and 122c are composed of portions 1215 and 1225 perpendicular to the longitudinal direction of the injector 130D, and portions 1216 and 1226 parallel to the longitudinal direction. The portions 1216 and 1226 parallel to the longitudinal direction concentrically extend such that the injector 130D has a structure of a triple pipe as a whole.

The gas inlet holes 141b to 143b of the respective chambers 131c to 133c are sequentially arranged downward from an upper portion of the injector 130D, along the longitudinal direction (vertical direction).

Configurations of the gas injection holes 151 to 153 are the same as those so far described except that they are arranged in the vertical direction to face the wafers W disposed inside the inner tube 424.

In this way, even in the vertical type heat treatment apparatus, it is possible to adjust a flow rate ratio of the vaporization raw material in the vertical direction with high accuracy through the use of the vaporization raw material supplying device 250 according to this embodiment, thus improving in-plane uniformity between the stacked wafers W.

### Ninth Embodiment

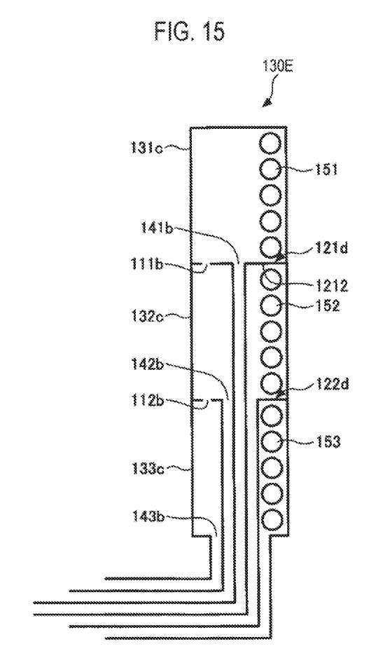

FIG. 15 is a view showing an example of an injector 130E of a substrate processing apparatus according to a ninth embodiment of the present disclosure. The substrate processing apparatus according to the ninth embodiment has an overall configuration that is the same as that of the substrate processing apparatus 305 according to the eighth embodiment shown in FIG. 13, except for a configuration of the injector 130E.

The injector 130E of the substrate processing apparatus according to the ninth embodiment is different from the injector 130D of the substrate processing apparatus 305 according to the eighth embodiment in that, as shown in FIG. 15, orifices 111b and 112b are formed in portions of partition walls 121d and 122d to allow the chambers 131c to 133c to communicate with one another.

In this way, the injector 130E may be configured such that the chambers 131c to 133c are in communication with one another by forming the orifices 111b and 112b in portions of the partition walls 121d and 122d. With this configuration, it is possible to constitute the injector 130E in a space-saving manner and at low cost as compared with the case where three independent injectors 131c to 133c are installed. Further, it is possible to uniformly distribute an amount of the vaporization raw material gas injected from the gas injection holes 151 to 153, which makes it possible to control flow rates with higher accuracy. In addition, the orifices 111b and 112b may be formed at any position as long as the chambers 131c to 13 3c are configured to communicate with one another.

Other components are the same as those of the substrate processing apparatus 305 according to the eighth embodiment, and therefore a description thereof is omitted.

### Tenth Embodiment

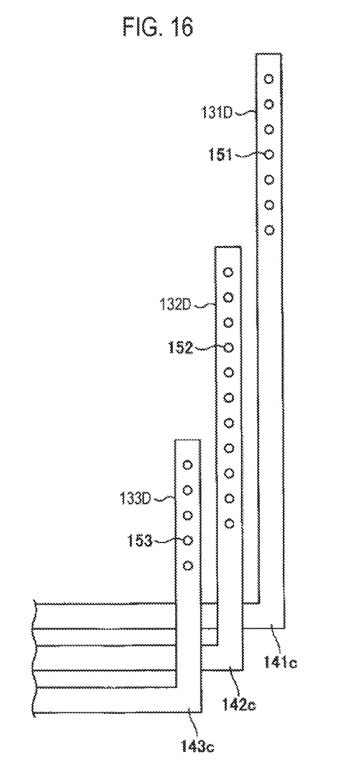

FIG. 16 is a view showing an example of injectors 131D to 133D of a substrate processing apparatus according to a tenth embodiment of the present disclosure. The substrate processing apparatus according to the tenth embodiment has an overall configuration that is similar to that of the substrate processing apparatus 305 according to the eighth embodiment shown in FIG. 13. However, the substrate processing apparatus according to the tenth embodiment is different from the substrate processing apparatuses 305 according to the eighth and ninth embodiments in that, as shown in FIG. 16, a plurality of injectors 131D to 133D configured to supply the vaporization raw material is installed and a plurality of gas injection holes 151 to 153 is formed in the respective injectors 131D to 133D such that the injectors 131D to 133D can supply the vaporization raw materials to different regions in the vertical direction of the process container 422.

The branch pipes 181 to 183 of the vaporization raw material supplying device 250 are connected to gas inlet holes 141c to 143c of the respective injectors 131D to 133D in a one-to-one basis such that each of the injectors 131D to 133D supply the vaporization raw material into the process container 422 at a flow rate set independently of one another. It can be said that the substrate processing apparatus according to the tenth embodiment is an example in which the substrate processing apparatus 300 according to the first embodiment is applied to a vertical type heat treatment apparatus.

As described above, the vaporization raw material may be supplied to a plurality of regions defined inside the process container 422 at a flow rate set independently of one another using the plurality of injectors 131d to 133d which is installed completely independently of one another.

As described above, it is possible to implement various types of substrate processing apparatuses by combining the vaporization raw material supplying device according to the above embodiments of the present disclosure with the plurality of injectors capable of supplying the vaporization raw material to the plurality of regions defined inside in the process container. This makes it possible to control flow rates for the respective regions with high accuracy, thus performing a substrate process with higher accuracy.

Further, in the first to tenth embodiments, the film formation process has been described by way of example. However, the substrate processing apparatuses according to the above embodiments of the present disclosure may be applied to various substrate processing apparatuses as long as they use a vaporization raw material such as an etching gas or the like. Further, the configurations of the injectors are not limited to the examples of the above embodiments, but may be applied to various types of injectors.

According to the present disclosure, it is possible to provide a vaporization raw material supplying device capable of adjusting a respective flow rate in each of multiple channels while achieving space saving, and a substrate processing apparatus using the same.

Although the preferred embodiments of the present disclosure have been described in detail, the present disclosure is not limited to the aforementioned embodiments, and various modifications and substitutions may be made to the aforementioned embodiments without departing from the scope of the present disclosure.

What is claimed is:

1. A vaporization raw material supplying device, comprising;
a single vaporization raw material producing part configured to vaporize a raw material to produce a vaporization raw material;
a plurality of branch pipes connected to the single vaporization raw material producing part and configured to distribute the produced vaporization raw material in multiple channels; and
a plurality of mass flow controllers installed respectively in the plurality of branch pipes.

2. The vaporization raw material supplying device of claim 1, wherein the single vaporization raw material producing part includes:
a storage tank storing the raw material therein; and
a heating part configured to heat the storage tank so as to vaporize the raw material.

3. The vaporization raw material supplying device of claim 2, wherein the storage tank is configured by an airtight container and is configured to hold the produced vaporization raw material therein.

4. The vaporization raw material supplying device of claim 1, wherein the plurality of branch pipes is coupled to the single vaporization raw material producing part through a single main pipe.

5. The vaporization raw material supplying device of claim 4, wherein the single main pipe includes a valve installed therein.

6. The vaporization raw material supplying device of claim 1, wherein each of the plurality of the branch pipes is connected directly to the single vaporization raw material producing part.

7. The vaporization raw material supplying device of claim 1, wherein each of the plurality of the branch pipes includes a valve installed therein.

8. The vaporization raw material supplying device of claim 1, further comprising: a casing configured to integrally house the single vaporization raw material producing part, the plurality of branch pipes and the plurality of mass flow controllers.

9. A substrate processing apparatus, comprising;
the vaporization raw material supplying device of claim 1;
a process container configured to accommodate substrates therein; and
an injector having a plurality of gas inlet holes and a plurality of gas injection holes, which are formed to correspond to a plurality of regions defined inside the process container,
wherein the plurality of branch pipes of the vaporization raw material supplying device is respectively connected to the plurality of gas inlet holes which are formed to correspond to the plurality of regions.

10. The substrate processing apparatus of claim 9, wherein the plurality of gas injection holes is formed to correspond to each of the plurality of regions.

11. The substrate processing apparatus of claim 9, wherein the injector includes a plurality of independent injectors which is independently installed to correspond to each of the plurality of regions.

12. The substrate processing apparatus of claim 11, wherein the plurality of regions has an area not overlapping with one another.

13. The substrate processing apparatus of claim 12, wherein adjacent regions among the plurality of regions have an area overlapping with each other.

14. The substrate processing apparatus of claim 9, wherein the injector includes a plurality of chambers partitioned by dividing an interior of the injector by partition walls, such that the plurality of chambers correspond to the plurality of regions, respectively.

15. The substrate processing apparatus of claim 14, wherein the plurality of chambers is spaces hermetically partitioned by the partition walls.

16. The substrate processing apparatus of claim 14, wherein some of the partition walls have communicating holes formed therein such that the plurality of chambers is in communication with one another.

17. The substrate processing apparatus of claim 14, wherein the plurality of chambers is arranged in a longitudinal direction of the injector.

18. The substrate processing apparatus of claim 14, wherein the plurality of gas inlet holes is formed in a lateral surface of the injector.

19. The substrate processing apparatus of claim 14, wherein the partition walls includes portions concentrically extending within the injector in a longitudinal direction of the injector, and the plurality of gas inlet holes is formed within the injector.

20. The substrate processing apparatus of claim 9, wherein each of the plurality of mass flow controllers sets a flow rate of the vaporization raw material to meet each of the plurality of regions connected through the plurality of branch pipes.

21. The substrate processing apparatus of claim 20, wherein the plurality of mass flow controllers include mass flow controllers having different maximum set flow rates depending on the flow rate set to meet each of the plurality of regions.
